(19) United States
(12) Patent Application Publication
(10) Pub. No.: US 2026/0144114 A1
(43) Pub. Date: May 21, 2026

(54) INTERSTITIAL MOUNTING OF COMPONENTS

(71) Applicant: BAE Systems Information and Electronic Systems Integration Inc., Nashua, NH (US)

(72) Inventors: Benjamin Terry, Cedard Rapids, IA (US); Jacob R. Mauermann, Marion, IA (US); Brian T. Louis, Norway, IA (US); Alan P. Boone, Swisher, IA (US)

(73) Assignee: BAE Systems Information and Electronic Systems Integration Inc., Nashua, NH (US)

(21) Appl. No.: 18/954,139

(22) Filed: Nov. 20, 2024

(51) Int. Cl. H01L 23/498; H01L 23/00; H01L 25/16

(52) U.S. Cl. CPC H10W 70/658; H10W 70/635; H10W 90/00; H10W 70/60; H10W 72/9415; H10W 72/9445; H10W 80/743; H10W 90/724

(57) ABSTRACT

A circuit card with interstitial surface mounted components. In an example, the circuit card includes a first surface; a second surface opposite the first surface; and an array of pads disposed on the first surface. The pads are configured to provide electrical coupling of the circuit card to a ball grid array of an electronic device. The circuit card also includes one or more interstitial electrical components mounted between the pads of the array on the first surface of the circuit card. The circuit card further includes one or more additional electrical components mounted on the second surface of the circuit card and on the first surface of the circuit card outside of a region comprising the array of pads. The electrical components may include capacitors, bypass capacitors, inductors, and/or resistors. The electronic device may be an integrated circuit or a field programmable gate array.

### FIELD OF DISCLOSURE

The present disclosure relates to surface mount components, and more particularly to interstitial mounting of components under a microelectronics package.

### BACKGROUND

Microelectronics packages generally include integrated circuits (e.g., field programmable gate arrays, application specific integrated circuits, etc.), and typically require supporting electrical components (e.g., resistors, capacitors, inductors, etc.) for proper operation. For example, bypass capacitors are employed for noise reduction to improve power quality delivered to circuitry within the package. These supporting components consume area on the circuit card to which the package is mounted, which can increase the size and cost of the circuit card.

### BRIEF DESCRIPTION OF THE DRAWINGS

FIG. 1 is a cross sectional view of a circuit card including surface mounted components.

FIG. 2 is a cross sectional view of a circuit card including interstitially surface mounted components, configured in accordance with certain embodiments of the present disclosure.

FIG. 3 is a top view of the circuit card of FIG. 2 including interstitially surface mounted components, configured in accordance with certain embodiments of the present disclosure.

FIG. 4 is a cross sectional view of a circuit card interposer including interstitially surface mounted components, configured in accordance with certain embodiments of the present disclosure.

FIG. 5 is a flowchart illustrating a methodology for fabrication of the circuit card of FIG. 2, in accordance with an embodiment of the present disclosure.

FIG. 6 is a flowchart illustrating a methodology for fabrication of the circuit card interposer of FIG. 4, in accordance with an embodiment of the present disclosure.

Although the following Detailed Description will proceed with reference being made to illustrative embodiments, many alternatives, modifications, and variations thereof will be apparent in light of this disclosure.

### DETAILED DESCRIPTION

Techniques are provided herein for interstitial mounting of components under a microelectronics package such as an integrated circuit of field programmable gate array (FPGA). As noted above, microelectronics packages typically require supporting electrical components (e.g., resistors, capacitors, inductors, etc.) for proper operation of the device, which may be a processor, memory, or logic circuit of any type. For example, bypass capacitors are often employed to improve power quality delivered to the package. These supporting components consume area on the circuit card to which the package is mounted, which can increase the size and cost of the circuit card. The circuit card may be referred to with different terminology, such as printed circuit board (PCB), PCB assembly (PCBA), circuit card assembly (CCA), printed circuit assembly (PCA), or printed wiring board (PWB). Any of these terms may be used herein interchangeably.

To this end, and in accordance with an embodiment of the present disclosure, techniques are provided for fabrication of a circuit card configured to mount supporting electrical components under the microelectronics package rather than (or in addition to) mounting the components around the footprint of the package. The disclosed techniques advantageously utilize the space between the ball grid array (BGA) pads or other array of contact pads on the circuit card to host the supporting electrical components.

In accordance with an embodiment, a circuit card with interstitial surface mounted components includes a first surface; a second surface opposite the first surface; and an array of pads disposed on the first surface. The pads are configured to provide electrical coupling of the circuit card to a BGA of an electronic device. The circuit card also includes one or more electrical components mounted between the pads of the array on the first surface of the circuit card. The circuit card further includes one or more additional electrical components mounted on the second surface of the circuit card and on the first surface of the circuit card outside of a region comprising the array of pads. The electrical components may include capacitors, bypass capacitors, inductors, and/or resistors. The electronic device may be an integrated circuit or an FPGA.

It will be appreciated that the techniques described herein may increase routing density and reduce product size by exploiting previously unused space on the circuit card under the microelectronics package, compared to other methods that consume surface area by mounting supporting electrical components outside the region of the microelectronics package. Although examples using BGA technology are described, the techniques may be used with other contact pad array technologies. For instance, pin grid array packages, column grid array packages, or any other packages having a contact array that includes underutilized space between conductive elements of the array, may also benefit from the techniques described herein. The techniques may also be used with interposers having such contact arrays. Numerous embodiments and applications will be apparent in light of this disclosure.

### Circuit Card Architecture

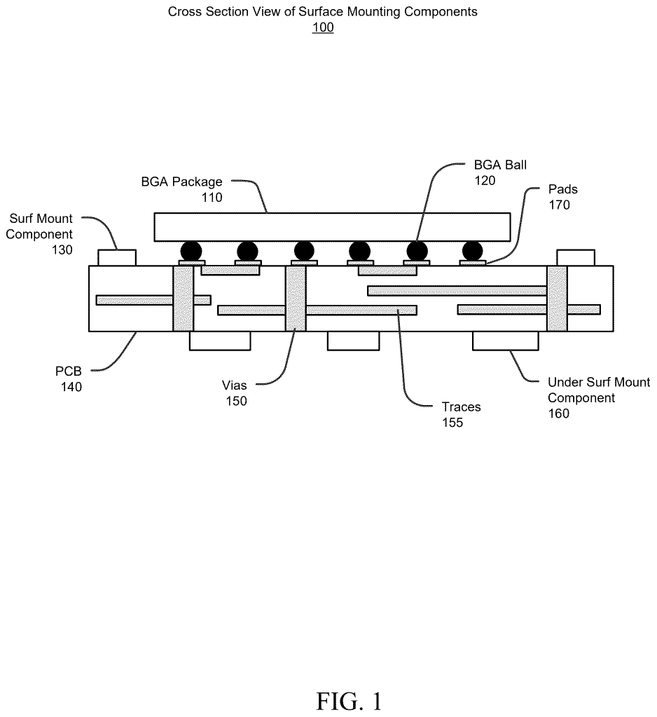

FIG. 1 is a cross sectional view 100 of a circuit card including surface mounted components. The circuit card or printed circuit board (PCB) 140 is shown to include a region in which a BGA packaged microelectronic device 110 may be mounted to the circuit card. This region comprises an array of pads 170, to which the balls 120 of the BGA package 110 are electrically coupled. Electrical components 130 are surface mounted in relative proximity to the BGA package but outside of the region in which the package is mounted to the circuit card (e.g., outside of the array of pads). The electrical components 130 may be configured to support the BGA package 110. In some embodiments, additional surface mounted components 160 may be mounted on the underside of the PCB 140. The PCB is also shown to include traces 155 and vias 150 which traverse the PCB both horizontally and vertically to provide electrical coupling between the pads 170 and the components 130, 160 and any other circuit elements.

Because the supporting electrical components 130 are mounted outside of the region that will be occupied by the BGA package 110, these components consume circuit card space that could be used for other purposes. This may result in a larger and more expensive circuit card.

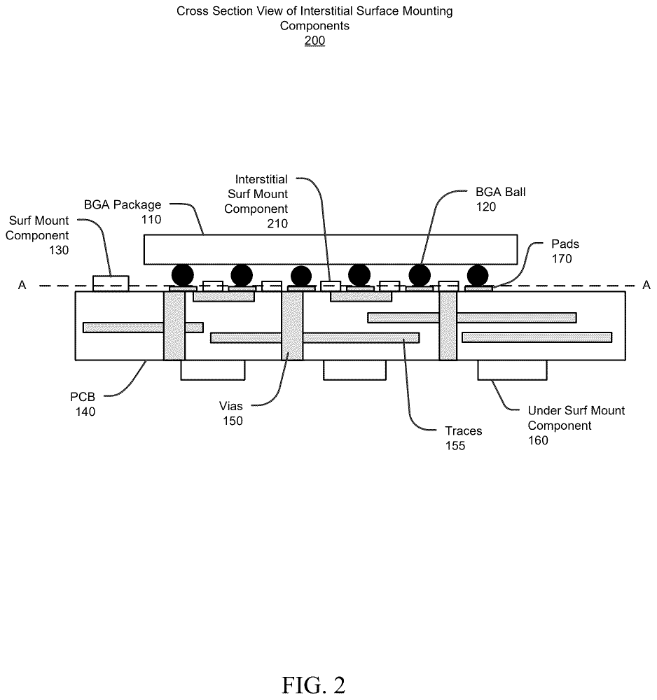

FIG. 2 is a cross sectional view 200 of a circuit card including interstitially surface mounted components, configured in accordance with certain embodiments of the present disclosure. In this embodiment, the circuit card or PCB 140 is again shown to include a region in which a BGA packaged microelectronic device 110 may be mounted to a surface (e.g., a top surface) of the circuit card. This region comprises an array of pads 170, to which the balls 120 of the BGA package 110 are electrically coupled. In this embodiment, however, certain supporting electrical components 210 are interstitially surface mounted components that are disposed between the pads 170 on the surface of the circuit card. By mounting the components 210 in this manner, the otherwise unused space under the BGA packaged microelectronics device 110 is advantageously exploited to increase the useable surface area of the PCB 140. This may allow for a smaller and less expensive product and/or increased routing density on the circuit card.

In some embodiments, additional electrical components 160 may be surface mounted on the opposite surface (e.g., the bottom surface) of the PCB 140. In some embodiments, yet further electrical components 130 may be surface mounted on the top surface of the PCB 140, outside of the region in which the BGA packaged microelectronic device 110 is mounted. Thus, a single PCB 140 can have upper surface mount components 130, under surface mount components 160 and interstitial surface mount components 210.

In some embodiments, the microelectronic device 110 may be an integrated circuit or FPGA configured to implement a processor, memory, or other logic circuit. In some embodiments, the electrical components 210, 160, and 130 may be capacitors, bypass capacitors, inductors, and/or resistors.

The PCB is also shown to include traces 155 and vias 150 which traverse the PCB both horizontally and vertically to provide electrical coupling between the pads 170 and the electrical components 210, 160, and 130. The interstitial surface mounted components 210, in one example, are electrically coupled by vias 150 extending vertically from the underside of the component and can traverse through the PCB 140 to the opposing side of the PCB to electrical connections or other surface mount components 160. Traces 155 are used in other embodiments to electrically couple the interstitial components 210 horizontally within the PCB 140 and can connect to the pads 170 of BGA balls 120 or to other interstitial components 210. In yet a further example, the traces and vias can be electrically coupled within the PCB 140 to route signals horizontally as well as vertically.

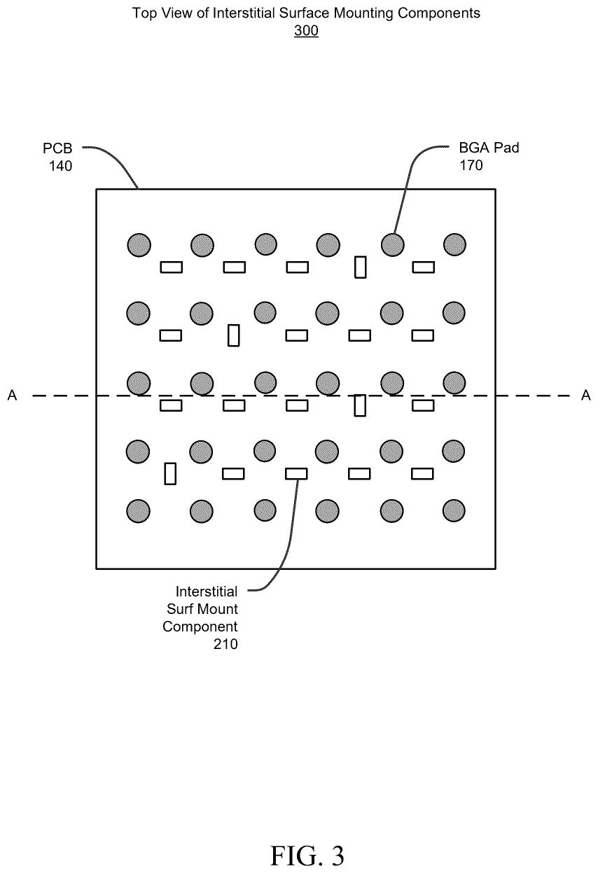

FIG. 3 is a top view 300 of the circuit card of FIG. 2 including interstitially surface mounted components, configured in accordance with certain embodiments of the present disclosure. This view illustrates the placement of interstitially surface mounted components 210 between the pads 170 on the top surface of the PCB 140. The layout of the components 210 is one possible example. In other embodiments, there may be more or fewer such components 210, and they may be disposed in any desired position and oriented in any desired direction that offers sufficient room to fit the components 210 between the pads 170.

An additional benefit provided by the use of interstitially surface mounted components is that the components, which are now mounted below the BGA package, are closer to the die inside the BGA package which results in a lower impedance electrical path. In the case in which the components are bypass capacitors, the lower impedance provides an improved power distribution network to the network.

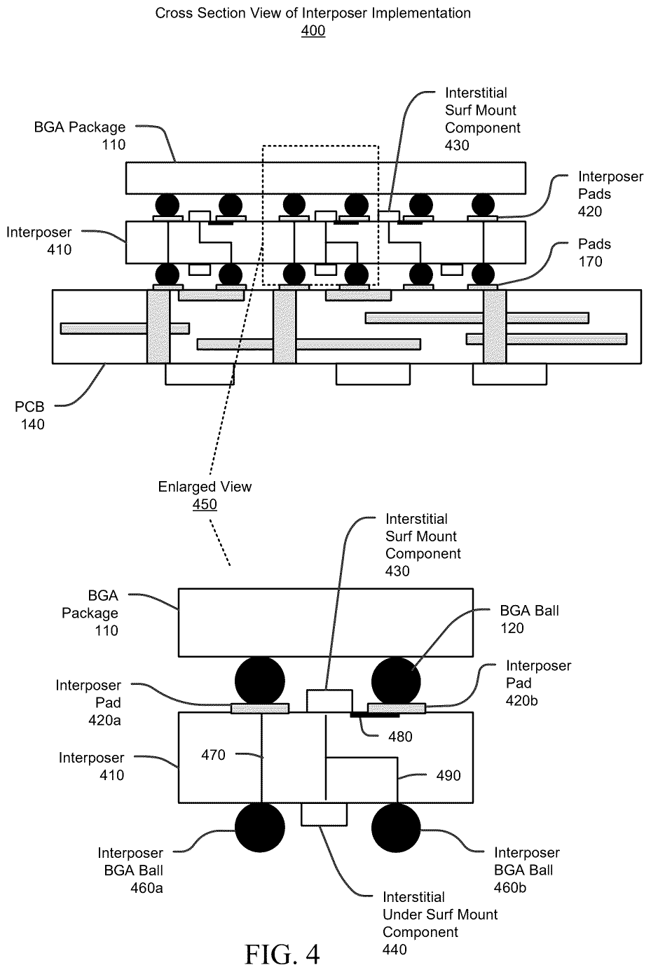

FIG. 4 is a cross sectional view 400 of a circuit card interposer including interstitially surface mounted components, configured in accordance with certain embodiments of the present disclosure. In this embodiment, an interposer card 410 is disposed between the BGA package 110 and the host circuit card or PCB 140. In some embodiments, the interposer card 410 may be fabricated as a laminated PCB. The interposer 410 is shown to include an array of interposer pads 420 to which the balls 120 of the BGA package 110 are electrically coupled. The interposer 410 is also shown to include interposer interstitially surface mounted components 430 which are disposed between the pads 420. The interposer further includes a BGA comprising interposer BGA balls 460 configured to electrically couple to the pads 170 of the PCB 140. In yet a further example the interposer 410 can have under surface mount components 440 mounted on the underside of the interposer 410.

An enlarged view 450 more clearly shows vias and traces 470, 480, and 490 within the interposer 410. For example, via 470 electrically couples an interposer pad 420a to an interposer BGA ball 460a. Trace 480 electrically couples an interposer pad 420b to an interposer interstitially mounted component 430. The trace and via combination 490 electrically couple the interposer interstitially mounted component 430 to an interstitially undermounted component 440 and an interposer BGA ball 460b.

The use of an interposer allows for the addition of product specific electrical components to the BGA package without requiring a redesign of the host circuit card.

### Methodology

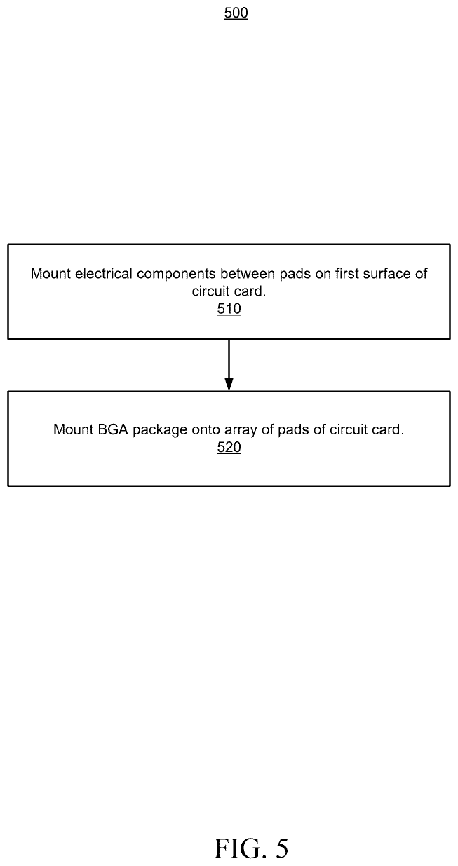

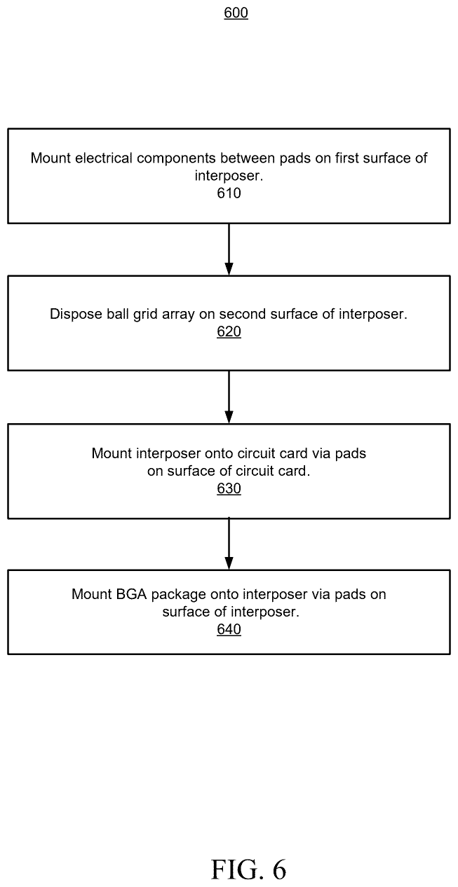

FIGS. 5 and 6 are flowcharts illustrating methodologies 500 and 600 for fabrication of circuit cards and interposers, in accordance with an embodiment of the present disclosure. As can be seen, example methods 500 and 600 include a number of phases and sub-processes, the sequence of which may vary from one embodiment to another. However, when considered in aggregate, these phases and sub-processes form a process for fabrication of circuit cards and interposers, in accordance with certain of the embodiments disclosed herein, for example as illustrated in FIGS. 2-4, as described above. However other system architectures can be used in other embodiments, as will be apparent in light of this disclosure. To this end, the correlation of the various functions shown in FIGS. 5 and 6 to the specific components illustrated in the figures, is not intended to imply any structural and/or use limitations. Rather other embodiments may include, for example, varying degrees of integration wherein multiple functionalities are effectively performed by one system. Numerous variations and alternative configurations will be apparent in light of this disclosure.

In one embodiment, method 500, for fabrication of the circuit card of FIG. 2, commences at operation 510, by mounting one or more electrical components between pads, of an array of pads, on the first surface of the circuit card. The first surface (which may be considered to be a top surface, for example) is the surface upon which an electronic device, is to be mounted. The pads are configured to provide electrical coupling of the circuit card to a ball grid array of the electronic device. In some embodiments, the electronic device (e.g., a microelectronic device in a BGA package) may be an integrated circuit or FPGA configured to implement a processor, memory, or other logic circuit. In some embodiments, the electrical components may be capacitors, bypass capacitors, inductors, and/or resistors.

At operation 520, the BGA package is mounted onto the array of pads on the first surface of the circuit card.

In some embodiments, additional operations may be performed, as previously described in connection with the system. For example, additional electrical components may be mounted on a second surface (e.g., the surface opposite the first surface, or the bottom surface) of the circuit card. In some embodiments, further additional components may be mounted on the first surface of the circuit card outside of the region comprising the array of pads.

In some embodiments, the circuit card is a PCB. The circuit card may be fabricated to include traces and vias within the circuit card that are configured to electrically couple the pads to the electrical components and to electrically couple the electrical components to other electrical components mounted on the circuit card.

In one embodiment, method 600, for fabrication of the circuit card interposer of FIG. 4, commences at operation 610, by mounting one or more interstitial electrical components between the pads, of an array of pads, on the first surface of the interposer. In some embodiments, the electrical components may be capacitors, bypass capacitors, inductors, and/or resistors. The interposer is a circuit card that is configured to interface between an electronic device and another circuit card or host circuit card. The first surface of the interposer (which may be considered to be a top surface, for example) is the surface upon which the electronic device is to be mounted. The pads are configured to provide electrical coupling of the interposer to a ball grid array of the electronic device. In some embodiments, the electronic device (e.g., a microelectronic device in a BGA package) may be an integrated circuit or FPGA configured to implement a processor, memory, or other logic circuit.

At operation 620, a ball grid array is disposed on a second surface (e.g., the surface opposite the first surface, or the bottom surface) of the interposer. The ball grid array is configured to provide electrical coupling to pads on the host circuit card.

In some embodiments, one or more additional interstitial electrical components may be mounted between the balls of the ball grid array, on the second surface of the interposer.

At operation 630, the interposer is mounted onto the circuit card via the pads on the surface of the host circuit card.

At operation 640, the BGA package is mounted onto the interposer via the pads on the first surface of the interposer.

In some embodiments, additional operations may be performed, as previously described in connection with the system. For example, the interposer may be fabricated to include traces and vias within the interposer circuit card. The traces and vias may be configured to electrically couple pads to the electrical components and to electrically couple the electrical components to the balls of the ball grid array. The traces and vias may also be configured to electrically couple the pads (that are not coupled to the electrical components) to the balls of the ball grid array.

Some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still cooperate or interact with each other.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system. The embodiments are not limited in this context.

The terms “circuit” or “circuitry,” as used in any embodiment herein, are functional and may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), desktop computers, laptop computers, tablet computers, servers, smartphones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Numerous specific details have been set forth herein to provide a thorough understanding of the embodiments. It will be understood, however, that other embodiments may be practiced without these specific details, or otherwise with a different set of details. It will be further appreciated that the specific structural and functional details disclosed herein are representative of example embodiments and are not necessarily intended to limit the scope of the present disclosure. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

### Further Example Embodiments

The following examples pertain to further embodiments, from which numerous permutations and configurations will be apparent.

Example 1 is a circuit card comprising: a first surface; a second surface opposite the first surface; an array of pads disposed on the first surface, the pads configured to provide electrical coupling of the circuit card to a ball grid array of a device; and one or more interstitial electrical components mounted between the pads of the array on the first surface of the circuit card.

Example 2 includes the circuit card of Example 1, wherein the one or more interstitial electrical components are a first group of electrical components, and the circuit card comprises a second group of electrical components, the second group of electrical components mounted on the second surface of the circuit card and/or on the first surface of the circuit card outside of a region comprising the array of pads.

Example 3 includes the circuit card of Example 2, comprising vias and traces configured to electrically couple the pads to the interstitial electrical components and/or the second group of electrical components.

Example 4 includes the circuit card of Example 2, comprising vias and traces configured to electrically couple the interstitial electrical components to the second group of electrical components.

Example 5 includes the circuit card of any of Examples 1-4, wherein the electrical components for the interstitial electrical component and/or the second group of electrical components are one or more of capacitors, inductors, or resistors.

Example 6 includes the circuit card of Example 5, wherein the capacitors are bypass capacitors.

Example 7 includes the circuit card of any of Examples 1-6, wherein the device is an integrated circuit or a field programmable gate array.

Example 8 includes the circuit card of Example 1, wherein the device is an interposer comprising: a first interposer surface; a second interposer surface opposite the first interposer surface; an array of interposer pads disposed on the first interposer surface, the interposer pads configured to provide electrical coupling to a ball grid array of an electronic device; a ball grid array disposed on the second interposer surface, the balls of the ball grid array disposed on the second interposer surface configured to provide electrical coupling to a circuit card; and one or more interstitial electrical components mounted between the pads of the array of interposer pads on the first interposer surface.

Example 9 is an interposer comprising: a first surface; a second surface opposite the first surface; an array of pads disposed on the first surface, the pads configured to provide electrical coupling to a ball grid array of an electronic device; a ball grid array disposed on the second surface, the balls of the ball grid array disposed on the second surface configured to provide electrical coupling to a circuit card; and one or more interstitial electrical components mounted between the pads of the array on the first surface of the interposer.

Example 10 includes the interposer of Example 9, comprising vias and traces configured to electrically couple the interstitial electrical components to the balls of the ball grid array disposed on the second surface.

Example 11 includes the interposer of Examples 9 or 10, comprising vias and traces configured to electrically couple the pads disposed on the first surface to the balls of the ball grid array disposed on the second surface.

Example 12 includes the interposer of any of Examples 9-11, wherein the interstitial electrical components are one or more of capacitors, inductors, or resistors.

Example 13 includes the interposer of any of Examples 9-12, wherein the electronic device is an integrated circuit or a field programmable gate array.

Example 14 is a method for fabrication of a circuit card, the method comprising: mounting one or more interstitial electrical components between pads, of an array of pads disposed on a surface of the circuit card, the pads configured to provide electrical coupling of the circuit card to a ball grid array (BGA) of an electronic device, the electronic device in a BGA package; and mounting the BGA package onto the array of pads.

Example 15 includes the method of Example 14, wherein the surface is a first surface, the one or more interstitial electrical components are a first group of electrical components, and the method further comprises mounting a second group of electrical components on a second surface of the circuit card, the second surface opposite the first surface.

Example 16 includes the method of Example 15, further comprising forming vias and traces within the circuit card, the vias and traces configured to electrically couple the pads to the interstitial electrical components and/or the second group of electrical components.

Example 17 includes the method of any of Examples 14-16, wherein the one or more interstitial electrical components are a first group of electrical components, and the method further comprises mounting a second group of electrical components on the surface of the circuit card outside of a region comprising the array of pads.

Example 18 includes the method of Example 17, further comprising forming vias and traces within the circuit card, the vias and traces configured to electrically couple the first group of interstitial electrical components to the second group of electrical components.

Example 19 includes the method of any of Examples 14-18, wherein the electrical components for the interstitial electrical component and/or the second group of electrical components are one or more of capacitors, inductors, or resistors.

Example 20 includes the method of any of Examples 14-19, wherein the electronic device is an integrated circuit or a field programmable gate array.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A circuit card comprising:
a first surface;
a second surface opposite the first surface;
an array of pads disposed on the first surface, the pads configured to provide electrical coupling of the circuit card to a ball grid array of a device; and
one or more interstitial electrical components mounted between the pads of the array on the first surface of the circuit card.

2. The circuit card of claim 1, wherein the one or more interstitial electrical components are a first group of electrical components, and the circuit card comprises a second group of electrical components, the second group of electrical components mounted on the second surface of the circuit card and/or on the first surface of the circuit card outside of a region comprising the array of pads.

3. The circuit card of claim 2, comprising vias and traces configured to electrically couple the pads to the interstitial electrical components and/or the second group of electrical components.

4. The circuit card of claim 2, comprising vias and traces configured to electrically couple the interstitial electrical components to the second group of electrical components.

5. The circuit card of claim 1, wherein the electrical components for the interstitial electrical component and/or the second group of electrical components are one or more of capacitors, inductors, or resistors.

6. The circuit card of claim 5, wherein the capacitors are bypass capacitors.

7. The circuit card of claim 1, wherein the device is an integrated circuit or a field programmable gate array.

8. The circuit card of claim 1, wherein the device is an interposer comprising:
a first interposer surface;
a second interposer surface opposite the first interposer surface;
an array of interposer pads disposed on the first interposer surface, the interposer pads configured to provide electrical coupling to a ball grid array of an electronic device;
a ball grid array disposed on the second interposer surface, the balls of the ball grid array disposed on the second interposer surface configured to provide electrical coupling to a circuit card; and
one or more interstitial electrical components mounted between the pads of the array of interposer pads on the first interposer surface.

9. An interposer comprising:
a first surface;
a second surface opposite the first surface;
an array of pads disposed on the first surface, the pads configured to provide electrical coupling to a ball grid array of an electronic device;
a ball grid array disposed on the second surface, the balls of the ball grid array disposed on the second surface configured to provide electrical coupling to a circuit card; and
one or more interstitial electrical components mounted between the pads of the array on the first surface of the interposer.

10. The interposer of claim 9, comprising vias and traces configured to electrically couple the interstitial electrical components to the balls of the ball grid array disposed on the second surface.

11. The interposer of claim 9, comprising vias and traces configured to electrically couple the pads disposed on the first surface to the balls of the ball grid array disposed on the second surface.

12. The interposer of claim 9, wherein the interstitial electrical components are one or more of capacitors, inductors, or resistors.

13. The interposer of claim 9, wherein the electronic device is an integrated circuit or a field programmable gate array.

14. A method for fabrication of a circuit card, the method comprising:
mounting one or more interstitial electrical components between pads, of an array of pads disposed on a surface of the circuit card, the pads configured to provide electrical coupling of the circuit card to a ball grid array (BGA) of an electronic device, the electronic device in a BGA package; and
mounting the BGA package onto the array of pads.

15. The method of claim 14, wherein the surface is a first surface, the one or more interstitial electrical components are a first group of electrical components, and the method further comprises mounting a second group of electrical components on a second surface of the circuit card, the second surface opposite the first surface.

16. The method of claim 15, further comprising forming vias and traces within the circuit card, the vias and traces configured to electrically couple the pads to the interstitial electrical components and/or the second group of electrical components.

17. The method of claim 14, wherein the one or more interstitial electrical components are a first group of electrical components, and the method further comprises mounting a second group of electrical components on the surface of the circuit card outside of a region comprising the array of pads.

18. The method of claim 17, further comprising forming vias and traces within the circuit card, the vias and traces configured to electrically couple the first group of interstitial electrical components to the second group of electrical components.

19. The method of claim 14, wherein the electrical components for the interstitial electrical component and/or the second group of electrical components are one or more of capacitors, inductors, or resistors.

20. The method of claim 14, wherein the electronic device is an integrated circuit or a field programmable gate array.
